(19) United States
(12) Patent Application Publication
(10) Pub. No.: US 2026/0360425 A1
(43) Pub. Date: Nov. 12, 2026

(54) Resistive Memory Elements

(71) Applicant: Cirrus Logic International Semiconductor Ltd., Edinburgh (GB)

(72) Inventors: John P. LESSO, Edinburgh (GB); Alexander BARR, Austin, TX (US)

(73) Assignee: Cirrus Logic International Semiconductor Ltd., Edinburgh (GB)

(21) Appl. No.: 19/424,793

(22) Filed: Dec. 18, 2025

Related U.S. Application Data
(60) Provisional application No. 63/803,018, filed on May 9, 2025.

(51) Int. Cl. G11C 13/00

(52) U.S. Cl. CPC G11C 13/0069; G11C 13/004

(57) ABSTRACT

A resistive memory element, comprising: a first semiconductor switch coupled between a first voltage node and an output node; a second semiconductor switch coupled between the output node and a second voltage node, wherein on application of a first voltage at the first voltage node and a second voltage at the second voltage node, an output voltage at the output node defines a state of the resistive memory element, the state is programmable through adaptation of a first threshold voltage of the first semiconductor switch or a second threshold voltage of the second semiconductor switch.

### TECHNICAL FIELD

The present disclosure relates to resistive memory elements.

### BACKGROUND

Key-based authentication techniques typically involve applying a challenge to a function which generates a response based on a secret key. Keys used for KBA are typically stored in non-volatile memory, such as non-voltage random access memory (NVRAM). It can be costly to manufacture NVRAM on chip or add NVRAM to a wafer.

### SUMMARY

According to an aspect of the disclosure, there is provided a resistive memory element, comprising: a first semiconductor switch coupled between a first voltage node and an output node; a second semiconductor switch coupled between the output node and a second voltage node, wherein on application of a first voltage at the first voltage node and a second voltage at the second voltage node, an output voltage at the output node defines a state of the resistive memory element. The state may be programmable through adaptation of a first threshold voltage of the first semiconductor switch or a second threshold voltage of the second semiconductor switch.

The first threshold voltage and the second threshold voltage may be adaptable.

The first and/or second threshold voltages adaptable adaptable through hot carrier injection.

The first and second semiconductor switches may each comprise a MOSFET device. Each MOSFET device may comprise an NMOS device. A gate and source of each MOSFET device may be coupled together. Each MOSFET device may be configured in a subthreshold mode of operation.

The first and second semiconductor switches may each comprise a charge-trap transistor (CTT). The first and/or second threshold voltages may be adaptable through oxide tunnelling.

The state may define a binary data bit, such as a “0” or a “1”.

According to an aspect of the disclosure, there is provided memory, comprising at least one resistive memory element as described above.

The at least one resistive memory element may comprise a plurality of resistive memory elements.

Each of the plurality of resistive memory elements may be independently programmable through adaptation of their respective first and/or second threshold voltages.

States of a first subset of the plurality of resistive memory elements may form a per-device key unique to a first device into which the memory is incorporated. States of a second subset of the plurality of resistive memory elements may be programmed with a per-batch key unique to the first device and a plurality of additional devices (e.g. a batch of device comprising the first device).

The states of the first subset of the plurality of resistive memory elements may be dependent on a natural entropy of the first subset.

The memory may further comprise: control circuitry configured, during a read operation, to: for each of the at least one resistive memory elements, apply a first voltage at the first voltage node and a second voltage at the second voltage node, the first voltage being higher than the second voltage; measure an output voltage at the output node; and determine the state of the resistive memory element based on the output voltage.

The control circuitry may be configured, during a programming operation, to: program the resistive memory element by adapting the first and/or second threshold voltages.

Programming the resistive memory element may comprise: applying a first programming voltage at the first voltage node, a second programming voltage at the second voltage node, and a third programming voltage at the output node, the first voltage higher than the second and third voltages.

Determining the state of the resistive memory element may comprise comparing the output voltage to a predetermined reference voltage.

The control circuitry may comprise: an inverter or comparator configured to generate a binary output representing the state.

The control circuitry may be configured to: on initialisation of the memory, for each of the resistive memory element, determine the state of the resistive memory element; and program the resistive memory element by adapting the first and/or second threshold voltages to reinforce the state.

Reinforcing the state may comprise increasing a difference between the output voltage and a predetermined reference voltage.

According to an aspect of the disclosure, there is provided a physically unclonable function (PUF) comprising memory as described above.

According to an aspect of the disclosure, there is provided an electronic device comprising the resistive memory element, memory, or PUF described above.

The electronic device may comprise one of a mobile computing device, a laptop computer, a tablet computer, a games console, a remote-control device, a home automation controller or a domestic appliance, a toy, a robot, an audio player, a video player, or a mobile telephone, and a smartphone.

The electronic device may comprise one of a mobile computing device, a laptop computer, a tablet computer, a games console, a remote-control device, a home automation controller or a domestic appliance, a toy, a robot, an audio player, a video player, or a mobile telephone, and a smartphone.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of a system implementing key based authentication;

FIG. 2 is a schematic diagram of a resistive memory element;

FIG. 3 is a graphical illustration of a probability distribution of output voltages and a bit error rate of the memory element of FIG. 2 before programming;

FIG. 4 is a graphical illustration of the probability distribution of output voltages and the bit error rate of the memory element of FIG. 2 after programming;

FIG. 5 is a graphical illustration of the effect of high temperature on the probability distribution of output voltages and the bit error rate of the memory element of FIG. 2; and

FIG. 6 is a schematic diagram of an example memory comprising the memory element of FIG. 2.

### DESCRIPTION OF EMBODIMENTS

Key-based authentication is a method of confirming the identity of an entity (e.g. person, device or system) using secret (usually cryptographic) keys. To verify the integrity of a secret key held by the entity as part of a key-based authentication process, a challenge C may be sent to the entity. The entity may then respond with a transformation (a response R) of that challenge C which is transformed using their (private) key. The response R can then be checked to verify the key and thus the entity's identity.

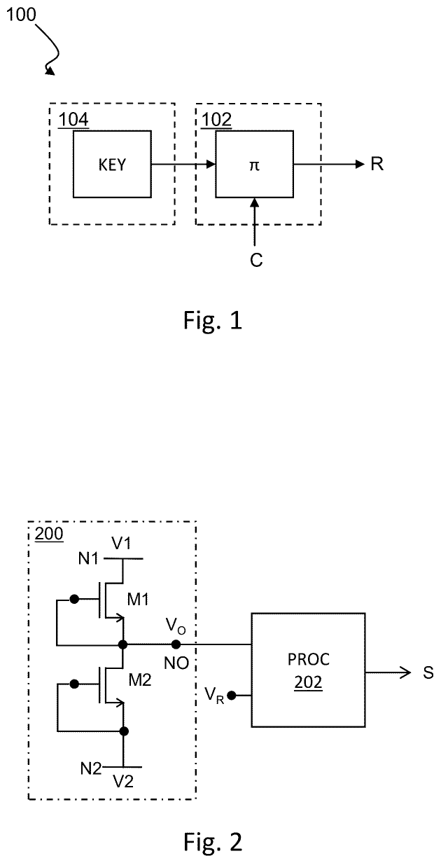

FIG. 1 is a schematic diagram of an example of the above key-based authentication scheme which may be implemented by a system 100 comprising a processor 102 and memory 104. The challenge C from is provided to a transformation function TT implemented on the processor 102. The function IT obtains a key KEY from the memory 104 and generates the response R. The response R may then be reviewed, for example by a verifier, to determine whether the key is valid. For example, the response R may be compared to an expected response to the challenge C.

Keys used for KBA, such as the key KEY described above, are typically stored in non-volatile memory, specifically non-voltage random access memory (NVRAM). However, adding NVRAM to standard CMOS wafers increases overall wafer cost and complexity, due to such device structures requiring process steps that are not part of conventional CMOS logic flow.

Embodiments of the present disclosure aim to address or at least ameliorate one or more of the issues associated with storing private keys in conventional NVRAM, such as that used to store cryptographic keys.

The inventors have realised that in subthreshold NMOS device configurations, it is possible to construct a resistive memory element that stores information in transistor threshold voltages (VTs) of metal-oxide-semiconductor field-effect transistors (MOSFETs). Furthermore, using techniques of hot carrier injections (HCl) and/or tunnelling, adjustments or adaptations can be made to threshold voltages of such MOSFETs. Such adjustments can be used either to program memory elements (e.g. change their state) or reinforce memory elements (i.e. reinforce or strengthen their state whilst not changing their state).

FIG. 2 is a schematic diagram of a resistive memory element 200 according to embodiments of the present disclosure. The memory element 200 comprises a first semiconductor switch M1 coupled between a first reference voltage node N1 and an output node NO, and a second semiconductor switch M2 coupled between a second reference voltage node N2 and the output node NO.

The first reference voltage node N1 may be coupled to a first reference voltage V1, e.g. VDD. The second reference voltage node N2 may be coupled to a second reference voltage V2, e.g. ground or zero volts. The first reference voltage may be higher than the second reference voltage.

In the embodiment shown in FIG. 2, the first and second semiconductor switches M1, M2 are implemented as NMOS MOSFET devices. It will be appreciated, however, that the present disclosure is not so limited. For example, the first and second semiconductor switches M1, M2 may alternatively be implemented as PMOS devices. Additionally, or alternatively, the first and second semiconductor switches M1, M2 may alternatively be implemented using another transistor switch technology, non-limiting examples including junction FETs, bipolar junction transistors (BJTs), FinFETs, tunnel FETs etc. Alternatively, the first and second semiconductor switches M1, M2 may be implemented as charge trap transistors (CTTs).

Accordingly, in the implementation shown in FIG. 2, a drain of the first semiconductor switch M1 is coupled to the first reference voltage node N1 and a source of the first semiconductor switch M1 is coupled to the output node NO. A drain of the second semiconductor switch M2 is coupled to the output node NO and a source of the second semiconductor switch M2 is coupled to the second reference voltage node N2.

To maintain the first and second semiconductor switches M1, M2 in a subthreshold (i.e. weak inversion) mode of operation, the gate-source voltages VGS1, VGS2 of respective switches M1, M2 should be maintained below their respective threshold voltage VTH1, VTH2. To achieve this, the gate and source of first semiconductor switch M1 are coupled together, and the gate and source of the second semiconductor switch M2 are coupled together. This forces respective gate-source voltage VGS1, VGS2 toward zero ensuring the first and second semiconductor switches M1, M2 are maintained in a subthreshold conduction mode. This enables an exponential current response based on respective first and second threshold voltages VTH1, VTH2.

In the configuration shown in FIG. 2, the first and second semiconductor switches M1, M2 have respective drain-source resistances R1, R2 which are proportional to their respective first and second threshold voltage VTH1, VTH2. When the first and second voltage V1, V2 are applied to respective first and second voltage nodes N1, N2, the memory element 200 acts as a potential (or voltage) divider, the output voltage VO at the output node NO proportional to the first and second threshold voltages VTH1, VTH2.

The drain source current IDS flowing in the first and second semiconductor switches M1, M2 can be represented by the following equation.

$${I}_{DS} = {I}_{0} {e}^{\frac{{V}_{GS} - {V}_{TH}}{{nV}_{T}} \{ 1 - {e}^{\frac{- {V}_{DS}}{{V}_{T}}} \}}$$

Where VDS is the drain source voltage, VTH is the threshold voltage, VT is the thermal voltage, (kT/q), n is the subthreshold slope factor, and I0 is the current scale factor which is proportional to width W and length L of respective switches M1, M2.

The above equation can be solved for the two switches M1, M2 where for the first switch M1, VDS=V1−VO, and for the second switch M2 VDS=VO−V2. If V1>2VT, the two equations can be approximated since the switches M1, M2 are operated in subthreshold saturation (which acts to reduce VDS sensitivity), leading to the following relationship.

$${V}_{O} \approx \frac{{V}_{1}}{2} - \frac{Δ {V}_{TH 1}}{2} + \frac{Δ {V}_{TH 2}}{2}$$

Thus, the output voltage VO is proportional to the threshold voltages VTH1, VTH2 of the first and second switches M1, M2 of the resistive memory element 200.

This characteristic or the resistive memory element 200 can be used to store data. For example, the output voltage VO may define a bit, such as a binary bit of data. For example, if the output voltage VO is greater than a predetermined reference voltage VR, the resistive memory element 200 may be deemed to be in a first state (e.g. “1”), and if the output voltage VO is less than the predetermined reference voltage VR, the resistive memory element 200 may be deemed to be in a second state (e.g. “0”).

Referring again to FIG. 2, processing circuitry 202 may be provided to generate and output a state S of the resistive memory element 200 based on the output voltage VO. For example, the processing circuitry 202 may be configured to compare the output voltage VO to the predetermined reference voltage VR. Where the switches M1, M2 are substantially identical, the predetermined reference voltage VR may be set to half the difference between the first and second voltages V1, V2, i.e. (V1−V2)/2. For example, the processing circuitry 202 may comprise an inverter or other suitable buffer configured to generate the state S as a binary output of e.g. VLOW and VHIGH. For example, the processing circuitry 202 may comprise a comparator configured to compare the output voltage VO to the predetermined reference voltage VR.

It will be appreciated that the threshold voltages VTH1, VTH2 of the switches M1, M2 of the resistive memory element 200 will have an inherent voltage level set by design during their manufacture. It will also be appreciated that these values will vary from device-to-device due to subtle variations in manufacturing conditions, leading to threshold voltage mismatch.

The inventors have realised that this threshold voltage mismatch can be used as a source of entropy, for example for use in security such as building physically unclonable functions (PUFs). As will be described in more detail below, a memory array may be built from multiple instances of the resistive memory element 200, the exact threshold voltages VTH1, VTH2 of each memory element 200 having some entropy which leads to very slight variation (and therefore entropy) of the output voltage VO measured at the output node NO. This uncertainty can then be used to generate wholly random keys.

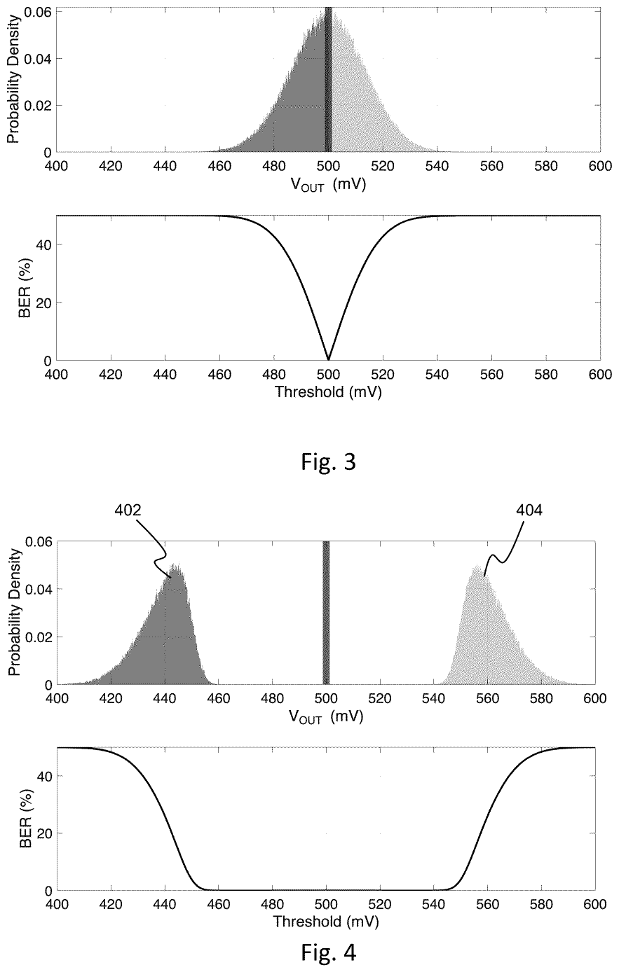

FIG. 3 graphically illustrates a probability density function of the output voltage VO of physically manufactured instances of the resistive memory element 200 of FIG. 2. FIG. 3 is a graph of threshold voltage of either of the first and second switches M1, M2 against bit error rate (BER). It can be seen that the output voltage VO has a normal distribution about 500 mV with a first voltage V1 of 1 V and a second voltage V2 of zero voltage. Thus, around half of resistive memory elements 200 have the first threshold voltage VTH1 greater than second threshold voltage VTH2 and vice versa. So, the state of each memory element 200 may be defined by whether the respective output voltage VO is greater or less than a reference voltage VR of 500 mV. It can also be seen from FIG. 3 that most of resistive memory elements 200 in the example have an output voltage VO very close to 500 mV, e.g. between 490 and 510 mV, which results in a high bit error rate.

To reduce the BER in state decisions for instances of the memory element 200, the first or second threshold voltage VTH1, VTH2 may be adjusted. For example, the threshold voltages VTH1, VTH2 may be adjusted to reduce the output voltage VO of memory elements 200 having an output voltage VO less than 500 mV and increase the output voltage VO of memory elements 200 having an output voltage greater than 500 mV. For example, by increasing the first threshold voltage VTH1, the resistance of the first switch M1 will increase, leading to a decrease in the output voltage VO. Conversely, by increasing the second threshold voltage VTH2 whilst maintaining the second threshold voltage VTH1 constant, the resistance R2 of the second switch M2 will increase, leading to an increase in the output voltage.

FIG. 4 graphically illustrates a probability density function of the output voltage VO of instances of the resistive memory element 200 of FIG. 2, their output voltages VO adjusted by adjustment of first and second threshold voltages VTH1, VTH2 in the manner described above. It can be seen that this adjustment leads to a first group 402 of memory elements 200 having an output voltage substantially lower than the reference voltage VR, and a second group 404 of memory elements 200 having an output voltage VO substantially higher than the reference voltage VR. This reduces the BER to zero leading to a substantially improvement in robustness of the memory elements 200.

Adjustment of threshold may also be performed to program a state of the memory element 200 to whatever state is desired by adjusting one of the first and second threshold voltage VTH1, VTH2. For example, programming may be performed to reinforce a state (e.g. from “1” to more “1”), as is shown in FIG. 4. Alternatively, programming may be performed to change a state (e.g. from “1” to “0”).

Threshold voltage adjustment may be achieved in any manner known in the art. Such techniques depend on the switch technology used for the first and second switches M1, M2.

Where the switches M1, M2 are implemented in CMOS, the first and/or second threshold voltages VTH1, VTH2 may be increased by way of hot carrier injection (HCl). This may be achieved by applying a high drain-to-source voltage VDS (e.g. approximately 5V or above) between the source and drain of respective switches M1, M2. For example, to increase the threshold voltage of the first switch M1, a relatively high voltage may be applied to the first node N1 (drain of N1) and a relatively low voltage applied to the output node NO (source of M1) leading to a large drain-source voltage VDS across the first switch M1. For example, to increase the threshold voltage of the second switch M2, a relatively high voltage may be applied to the output node NO (drain of M2) and a relatively low voltage applied to the second node N2 (source of M2) leading to a large drain-source voltage VDS across the second switch M1. The voltage potential between drain and source of the switches M1, M2 may be pulsed to induce threshold voltage change.

The drain-source voltage VDS applied is preferably large enough to cause permanent defects in and near the gate oxide layer of a given switch M1, M2.

Application of such a potential difference causes carriers to accelerate to very high kinetic energies (hot), causing charge trapping in the gate oxide layer and permanent interface trap generation (due to breaking of Si—H bonds at the interface to the gate oxide (e.g. Si/SiO2 interface).

It will be appreciated that charge trapping in the gate oxide layer is reversible. For example, by heating the first switch M1, carriers trapped in the gate oxide layer may escape causing a reduction in threshold voltage VTH1. However, permanent damage associated with interface trap generation is irreversible, leading to a permanent net increase in threshold voltage VTH1 when a sufficiently high drain-source voltage VDS is applied across the first switch M1.

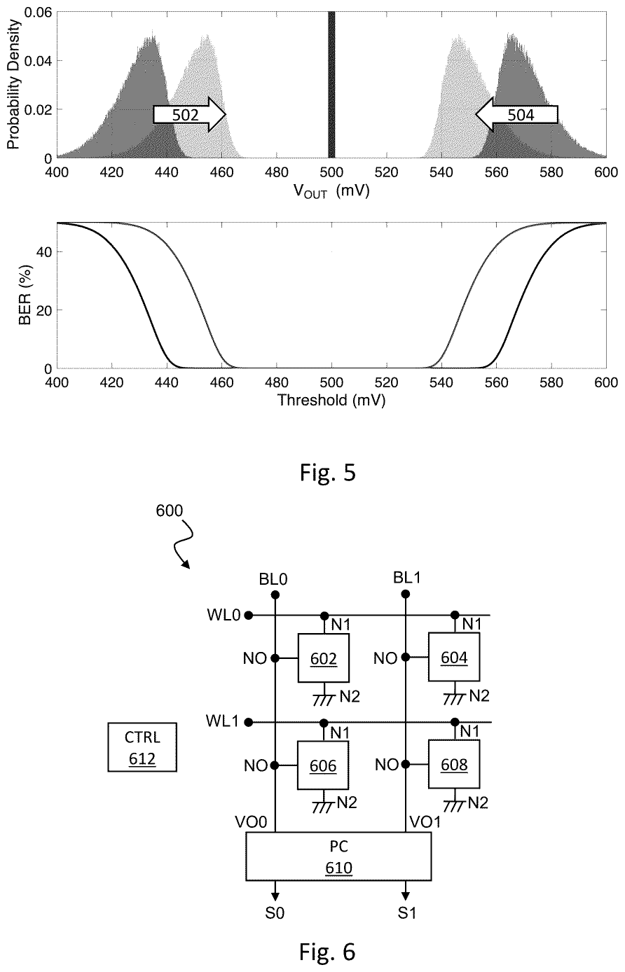

This phenomenon is illustrated in FIG. 5 which shows the effects of subsequent annealing the memory elements 200 having been programmed by threshold voltage adjustment. Comparing FIG. 5 to FIGS. 3 and 4, it can be seen that output voltages VO move from their values as seen in FIG. 4 closer to the reference voltage VR after annealing (as denoted by arrows 502, 504). However, output voltages VO do not return to their original natural values seen in FIG. 3. This reflects the above-described mechanisms at play, in which temporary threshold voltage increases due to charge trapping are substantially reversed whilst permanent interface trap generation is not reversed by annealing or heating of the memory element 200. FIG. 5 also shows a change in BER associated with the change in output voltage VO.

Where the first and second switches M1, M2 are implemented as charge trap transistors (CTTs), charge may be injected into a charge trapping layer of either switch M1, M2 to increase its threshold voltage. For example, referring to the first switch M1, this device may have a gate structure comprising charge trapping layer. The charge trapping layer may be programmed by applying several positive voltage pulses at the gate of the first switch M1 with its source coupled to a reference voltage lower than the voltage at the drain of the first switch M1, such as ground. This leads to tunnelling or hot carrier injection of carriers (e.g. electrons) into the charge trapping layer, which in turn leads to an increase in the first threshold voltage VTH1 of the first switch M1. Programming may alternatively be implemented by applying a constant positive voltage at the gate G. CTTs are known in the art and so will not be described in more detail here.

Thus, the memory element 200 supports both user-programmable memory via explicit threshold voltage adjustment through HCl, tunnelling or the like, and entropy-based programming, where naturally occurring threshold variations are latched to create a unique device fingerprint. In addition, naturally occurring threshold variations may be reinforced through programming to decrease bit error rate in such latching. The use of natural entropy associated with semiconductor manufacture may be useful for security applications such as physically unclonable functions (PUFs) or key-based authentication mechanisms.

As noted above, the memory element 200 may be incorporated into a memory array. For example, a memory array or device may comprise a plurality of the memory element 200. In doing so, data storage capacity increases and consequently the security of any device utilising the memory element in an authentication or cryptographic system may be increased. Implementation of a memory array comprising a plurality of the memory element 200 may be achieved in any conceivable manner.

FIG. 6 is a schematic diagram of one such possible technique for addressing a plurality of resistive memory elements 602, 604, 606, 608 of a memory 600. The memory 600 comprises the resistive memory elements 602, 604, 606, 608, processing circuitry 610, and control circuitry 612.

Each of the plurality of resistive memory element 602, 604, 606, 608 may comprise the resistive memory element 200 shown in FIG. 2 and the reference numerals for nodes of that memory element 200 have been adhered to in FIG. 6. In this example, the memory 600 comprises four memory elements 602, 604, 606, 608. However, embodiments are not so limited and fewer or more than four memory elements may be provided.

First voltage nodes N1 of first and second resistive memory elements 602, 604 are coupled to a first word line WL0. First voltage nodes N1 of third and fourth resistive memory elements 606, 608 are coupled to a second word line WL1. Second voltage nodes N2 of the first, second, third and fourth resistive memory elements 602, 604, 606, 608 are coupled to the second reference voltage (ground). Output nodes NO of the first and second resistive memory elements 602, 604 are coupled to a first bit line BL0. Output nodes NO of the third and fourth resistive memory elements 606, 608 are coupled to a second bit line BL1.

The first bit line BL0 and second bit line BL1 are coupled to the processing circuitry 610 which is configured to convert respective first and second output voltage VO0, VO1 to first and second states S0, S1.

The control circuitry 612 is configured to control voltages applied to the first and second word lines WL0, WL1 and the first and second bit lines BL0, BL1.

To read the first and/or second resistive memory elements 602, 604, the first voltage V1 may be applied to the first word line WL0 with the second word line WL1 held at zero volts. The output voltages VO0, VO1 are then processed by the processing circuitry 610 to determine first and second states of the first and second resistive memory elements 602, 604.

To read the third and/or fourth resistive memory elements 606, 608, the first voltage V1 may be applied to the second word line WL1 with the first word line WL0 held at zero volts. The output voltages VO0, VO1 are then processed by the processing circuitry 610 to determine states S0, S1 of the third and fourth resistive memory elements 606, 608.

The control circuitry 612 may be configured to adjust threshold voltages of either of the respective switches M1, M2 of any of the resistive memory elements 602, 604, 606, 608 by controlling voltages applied to the first and second bit lines BL0, BL1 and the first and second word lines WL0, WL1. Programming of the first and second threshold voltages VTH1, VTH2 may be in any manner known in the art, such as those techniques described above.

The plurality of memory elements 602, 604, 606, 608 may be used to store data pertaining to a device into which the memory 600 is integrated. Additionally, or alternatively, one or more of the plurality of memory elements 602, 604, 606, 608 may be used to store data pertaining to a batch of devices sharing a key. For example, a first subset of the plurality of memory elements 602, 604, 606, 608 may be programmed with a key pertaining to the device into which the memory 600 is integrated, and a second subset of the plurality of memory elements 602, 604, 606, 608 may be programmed with a key pertaining to a plurality or batch of devices including the device into which the memory 600 is integrated, that batch of devices sharing a key.

Thus, the present disclosure provides a novel resistive memory element leveraging HCl and/or tunnelling for programmable threshold voltages. It enables secure, cost-effective, and fabrication-friendly memory and identity solutions without requiring traditional NVRAM technology and process nodes.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog TM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A resistive memory element, comprising:
a first semiconductor switch coupled between a first voltage node and an output node;
a second semiconductor switch coupled between the output node and a second voltage node,
wherein on application of a first voltage at the first voltage node and a second voltage at the second voltage node, an output voltage at the output node defines a state of the resistive memory element, the state is programmable through adaptation of a first threshold voltage of the first semiconductor switch or a second threshold voltage of the second semiconductor switch.

2. The resistive memory element of claim 1, wherein the first threshold voltage and the second threshold voltage are adaptable.

3. The resistive memory element of claim 1, wherein the first and/or second threshold voltages are adaptable through hot carrier injection.

4. The resistive memory element of claim 1, wherein the first and second semiconductor switches each comprise a MOSFET device.

5. The resistive memory element of claim 4 wherein each MOSFET device comprises an NMOS device.

6. The resistive memory element of claim 4, wherein a gate and source of each MOSFET device are coupled together.

7. The resistive memory element of claim 4, wherein each MOSFET device is configured in a subthreshold mode of operation.

8. The resistive memory element of claim 1, wherein the first and second semiconductor switches each comprise a charge-trap transistor (CTT), wherein first and/or second threshold voltages are adaptable through oxide tunnelling.

9. The resistive memory element of claim 1, wherein the state defines a binary data bit.

10. A memory, comprising:
at least one resistive memory element according to claim 1.

11. The memory of claim 10, wherein the at least one resistive memory element comprises a plurality of resistive memory elements.

12. The memory of claim 11, wherein each of the plurality of resistive memory elements are independently programmable through adaptation of their respective first and/or second threshold voltages.

13. The memory of claim 11, wherein states of a first subset of the plurality of resistive memory elements form a per-device key unique to a first device into which the memory is incorporated and states of a second subset of the plurality of resistive memory elements are programmed with a per-batch key unique to the first device and a plurality of additional devices.

14. The memory of claim 13, wherein the states of the first subset of the plurality of resistive memory elements are dependent on a natural entropy of the first subset.

15. The memory of claim 10, further comprising:
control circuitry configured, during a read operation, to:
for each of the at least one resistive memory elements, apply a first voltage at the first voltage node and a second voltage at the second voltage node, the first voltage being higher than the second voltage;
measure an output voltage at the output node; and
determine the state of the resistive memory element based on the output voltage.

16. The memory of claim 10, wherein the control circuitry is configured, during a programming operation, to:
program the resistive memory element by adapting the first and/or second threshold voltages.

17. The memory of claim 16, wherein programming the resistive memory element comprises:
applying a first programming voltage at the first voltage node, a second programming voltage at the second voltage node, and a third programming voltage at the output node, the first voltage higher than the second and third voltages.

18. The memory of claim 15, wherein determining the state of the resistive memory element comprises comparing the output voltage to a predetermined reference voltage.

19. The memory of claim 18, wherein the control circuitry comprises:
an inverter or comparator configured to generate a binary output representing the state.

20. The memory of claim 15, wherein the control circuitry is configured to:
on initialisation of the memory, for each of the resistive memory element, determine the state of the resistive memory element; and
program the resistive memory element by adapting the first and/or second threshold voltages to reinforce the state.

21. The memory of claim 20, wherein reinforcing the state comprises increasing a difference between the output voltage and a predetermined reference voltage.

22. A physically unclonable function (PUF) comprising the memory of claim 10.

23. An electronic device comprising the resistive memory element of claim 1.

24. The electronic device of claim 23, wherein the device comprises one of a mobile computing device, a laptop computer, a tablet computer, a games console, a remote-control device, a home automation controller or a domestic appliance, a toy, a robot, an audio player, a video player, or a mobile telephone, and a smartphone.
